(19) United States
(12) Patent Application Publication
(10) Pub. No.: US 2026/0310109 A1
(43) Pub. Date: Oct. 8, 2026

(54) NANOIMPRINT LITHOGRAPHY MOLD AND NANOIMPRINT LITHOGRAPHY USING SAME

(71) Applicant: Taiwan Semiconductor Manufacturing Company, LTD., Hsinchu (TW)

(72) Inventor: Hsin-Yuan Lee, Hsinchu (TW)

(21) Appl. No.: 19/290,790

(22) Filed: Aug. 5, 2025

Related U.S. Application Data
(60) Provisional application No. 63/782,272, filed on Apr. 2, 2025.

(51) Int. Cl. G03F 9/00; B29C 43/18; B29C 43/58; B29L 31/34; G03F 7/00

(52) U.S. Cl. CPC G03F 9/7042; B29C 43/18; B29C 43/58; G03F 7/0002; G03F 9/7049; G03F 9/7092; B29C 2043/189; B29K 2905/00; B29K 2995/0012; B29L 2031/3406

(57) ABSTRACT

A nanoimprint lithography (NIL) mold includes a mold body, an imprint pattern formed on a front side thereof, and thermal expansion material disposed in and/or on the mold body. A NIL method includes imprinting a pattern of a mold onto a layer disposed on a semiconductor wafer by pressing the pattern onto the layer, and performing overlay correction during the NIL by heating a thermal expansion material disposed in and/or on the mold by applying light thereto. A method includes: forming a pre-layer on a substrate; forming a resist layer over the pre-layer; imprinting a mold into the resist layer; generating an adjusted mold by adjusting a position of a pattern of the mold by heating thermal expansion portions on the mold; patterning the resist layer using the adjusted mold; removing the mold from the resist layer; and transferring a pattern of the resist layer to the pre-layer.

This application claims the benefit of U.S. Provisional Application No. 63/782,272 filed Apr. 2, 2025. U.S. Provisional Application No. 63/782,272 filed Apr. 2, 2025 is incorporated herein by reference in its entirety.

### BACKGROUND

The following relates to the integrated circuit (IC) fabrication arts, nanoimprint lithography arts, overlay alignment arts, and related arts.

Imprint lithography in the context of semiconductor integrated circuit (IC) manufacturing is referred to as nanoimprint lithography (NIL). In this technique, a stamp (also referred to herein as a “mold” or “NIL mold” or “NIL mask” or similar nomenclature) is used to mechanically imprint features on a resist layer disposed on the semiconductor wafer, such as a monomer or polymer resist. NIL can provide advantages over optical lithography (also referred to a photolithography), such as the ability of NIL to imprint a three-dimensional pattern, such as with slanted sidewalls, into the resist layer. A challenge in NIL is precise alignment of the overlay of the NIL mold on the underlying (typically in-progress) IC structure previously formed on the semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a perspective view of a nanoimprint lithography (NIL) mold arranged to imprint on a wafer, in which the NIL mold includes light absorbing material for optical overlay compensation applied to the mold.

FIGS. 2A, 2B, 2C, 2D, and 2E diagrammatically illustrate an NIL method using a replica NIL mold, by way of successive side cut views.

FIGS. 3A, 3B, 3C, 3D, 3E, 3F, 3G, 3H, 3I, 3J, 3K, and 3L diagrammatically illustrate formation of an NIL mold shown in FIG. 3L, by way of successive side cut views shown in FIGS. 3A-3L.

FIGS. 4A, 4B, 4C, 4D, 4E, 4F, 4G, 4H, 4I, 4J, and 4K diagrammatically illustrate formation of an NIL mold blank shown in FIG. 4K, by way of successive side cut views shown in FIGS. 4A-4K.

FIG. 5 diagrammatically illustrates a cut view of a variant NIL mold blank similar to that of FIG. 4K.

FIGS. 6A, 6B, 6C, and 6D diagrammatically illustrates formation of an NIL mold shown in FIG. 6D from the NIL mold blank shown in FIG. 4K, by way of successive side cut views shown in FIGS. 6A-6D.

FIGS. 7 and 8 diagrammatically illustrates cut views of NIL molds according to two further nonlimiting illustrative mold embodiments.

FIG. 9 diagrammatically illustrates, by way of plan and side cut views, an NIL process including optical overlay compensation applied to the mold, according to three nonlimiting illustrative embodiments designated: Case 1, Case 2, and Case 3.

FIG. 10 diagrammatically illustrates Case 1 of FIG. 9 by some nonlimiting illustrative examples.

FIG. 11 diagrammatically illustrates Case 2 of FIG. 9 by some nonlimiting illustrative examples.

FIG. 12 diagrammatically illustrates Case 3 of FIG. 9 by some nonlimiting illustrative examples.

FIG. 13 diagrammatically illustrates a via formation process using NIL with optical overlay compensation as disclosed herein.

### DETAILED DESCRIPTION

The following disclosure provides various embodiments, or examples, for implementing various features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanoimprint lithography (NIL) uses a mold (or “stamp”, “mask”, “NIL mold”, “NIL stamp”, “NIL mask”, or similar nomenclature, considered synonymous herein) to mechanically imprint a pattern on a layer disposed on the semiconductor wafer. The layer may, for example, be a resist layer such as a monomer or polymer resist. In a nonlimiting illustrative NIL process, the resist is spin coated onto the semiconductor wafer. A pattern disposed on (e.g., etched into) a front side of the mold is pressed onto the resist layer to mechanically transfer the pattern to the resist layer. While the mold is pressed onto the resist layer, ultraviolet (UV) light is applied to cure the resist, after which the mold is removed, leaving the cured resist layer with the mechanically transferred pattern. NIL can provide features with critical dimension (CD) comparable to that obtainable by extreme ultraviolet (EUV) lithography.

For IC fabrication, the pattern imprinted by NIL should precisely align with and a pre-existing pattern disposed on and/or in the semiconductor wafer prior to performing of the NIL. This pre-existing pattern was created by prior IC fabrication process steps, which may include various combinations of etched patterns and/or spatially selective depositions, e.g., controlled by optical lithography, prior NIL steps, or so forth. To do so, an overlay error map is measured using microscopy or another suitable techniques, which quantifies the misalignment between the pattern of the mold and the pre-existing pattern disposed on and/or in the semiconductor wafer prior to performing of the NIL. There can be various types of overlay errors, such as translational misalignment, rotational misalignment, magnification error, various types of lens distortion, and so forth, and these overlay errors may result from a wide range of physical mechanisms, such as wafer warping due to different coefficients of thermal expansion (CTE) for different materials making up the IC chip undergoing fabrication, spatial thickness nonuniformities of deposited (or etched) layers over the area of the semiconductor wafer, additive (or aggregated) overlay errors over successive previous lithography steps, and/or so forth.

To provide overlay compensation in NIL, the NIL mold may be adjusted by finger actuators arranged to press against the lateral edges of the mold. The finger actuators may be piezoelectric actuators, electrostatic actuators, micro-stepper motors (e.g., implemented using MEMS), or the like. By adjusting the forces applied by the respective finger actuators, translational and rotational adjustment of the stamp can be realized. If all the finger actuators press inward with increased force, this can provide negative magnification, whereas if all the finger actuators press inward with reduced force, this can provide positive magnification. To provide adjustment of the IC chip to implement NIL overlay compensation, a laser or other light source illuminates a digital mirror device (DMD) to apply different levels of light to different portions of the IC die to generate a heat distribution in the IC chip that leads to thermal expansion or contraction of the IC chip.

However, these overlay compensation techniques may be insufficient and/or undesirable in certain cases. For example, the ability to use heating of the semiconductor wafer to achieve overlay compensation could be limited by thermal sensitivity of features of the pre-existing pattern disposed on and/or in the semiconductor wafer. As an example, an upper limit to wafer heating could be imposed by a “soft” or low melting-point material of the pre-existing pattern, since the heating could soften or melt such a material. The finger actuators may be limited in their ability to provide precise localized overlay compensation, since they operate on the mold as a whole. For example, if overlay compensation is needed only in a small region of the pattern, it may be difficult or impossible to optimize the finger actuator forces to provide this localized overlay compensation without adversely impacting overlay alignment elsewhere in the pattern.

Disclosed herein is an additional overlay compensation mechanism, which advantageously operates on the NIL mold (so that it is not limited by any thermal limits imposed by the materials of the IC under fabrication), can provide localized overlay compensation, and can provide both compressive and expansion mold adjustment. As further described by way of nonlimiting illustrative examples herein, the disclosed overlay compensation mechanism is implemented by adding thermal expansion material disposed on, and/or embedded in, the NIL mold. The thermal expansion material is caused to expand by applying light of a suitable wavelength (or waveband or spectrum) and optical power (or average optical power). The light-induced expansion of the thermal expansion material mechanically distorts the mold, and this effect is used herein to implement overlay compensation. It should be noted that this approach employing thermal expansion material integrated with the mold can be utilized alone, or in combination with overlay compensation provided by finger actuators operating on the periphery of the mold, or in combination with overlay compensation provided by heating the semiconductor wafer, or in combination with both overlay compensation provided by finger actuators and overlay compensation provided by wafer heating.

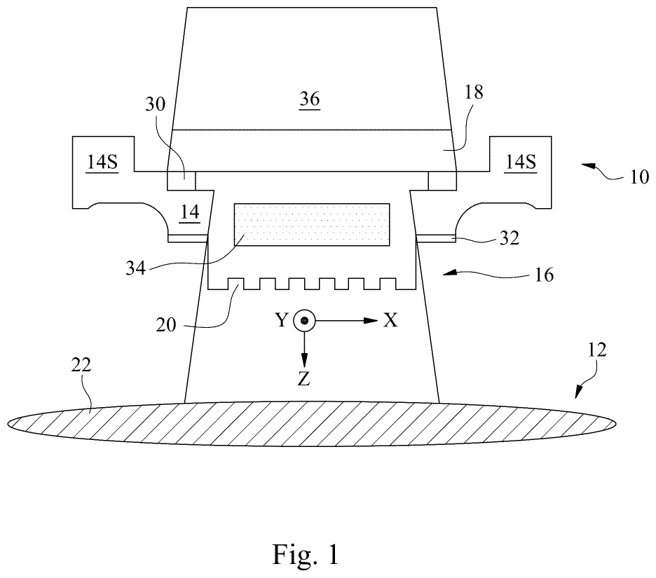

With reference to FIG. 1, a perspective view is diagrammatically shown of a nanoimprint lithography (NIL) mold 10 is shown arranged to imprint on a semiconductor wafer 12 (sometimes referred to herein as a wafer 12 or substrate 12 for brevity). The mold 10 includes a mold body 14 (also referred to herein as a substrate 14) having a front side 16 and a backside 18 opposite the frontside, and an imprint pattern 20 (sometimes referred to herein as a pattern 20 for brevity) formed on the front side 16 of the mold body 14. The front side 16 of the mold body 14 (or, more generally, of the mold 10) as used herein denotes the side of the mold body 14 that is pressed onto a resist layer or other layer 22 that is disposed on the semiconductor wafer 12; the backside 18 of the mold body 14 as used herein denotes the opposite side of the mold body 14, which faces away from the semiconductor wafer 12 when the pattern 20 is pressed onto the resist layer or other layer 22 disposed on the semiconductor wafer 12.

The mold body 14 is made of a rigid material which is transparent for any light that is to be passed through the mold 10 during the NIL process. For example, such light could be light used to heat the wafer 12, and/or ultraviolet light used to cure a resist layer into which the pattern 20 is being imprinted. In some nonlimiting examples herein, the mold body 14 is made of fused silica. More generally, the mold body 14 may comprise a ceramic material (of which fused silica is an example), or still more generally the mold body 14 may comprise another suitably rigid substrate material such as sapphire (a crystalline material), a glass oxide, or so forth. Again, these are nonlimiting examples. The mold body 14 could be a disk, or could be shaped. In the illustrative example, the mold body 14 is etched, machined, or otherwise processed to define an outboard support feature or features 14S that enable the NIL mold 10 to be secured in an NIL tool when using the mold 10 to perform NIL. The support feature(s) 14S could be an annular support ring, a plurality of support tabs arranged circumferentially around the mold body 14, or so forth. As previously noted, the support feature(s) 14S are optional, and may be included depending on the type of mold mounting mechanism employed by the NIL tool.

The pattern 20 is a three-dimensional pattern etched, engraved, or otherwise formed on the front side 16 of the mold body 14. FIG. 1 includes a notation of mutually orthogonal directions X, Y, and Z. The imprint pattern 20 is generally planar, lying in an X-Y plane, but may have some “height” in the third (Z) direction, although the height in the Z-direction is typically substantially smaller than the area of the pattern 20 in the X-Y plane. The pattern 20 may also have (for example) features with sidewalls that are slanted respective to the Z-direction, or may have other complex geometries.

The mold 10 further includes nonlimiting illustrative thermal expansion material 30, 32, and 34 used as disclosed herein for overlay compensation. The nonlimiting illustrative thermal expansion material 30 and 32 is peripheral thermal expansion material 30 and 32, so-called herein because the peripheral thermal expansion material 30 and 32 is disposed outside the pattern 20 of the mold 10. That is, the pattern 20 has an area in the X-Y plane, and the peripheral thermal expansion material 30 and 32 is located outside of this area. (Note that the area in the X-Y plane of the pattern 20 may also be referred to herein as the pattern field.) The peripheral thermal expansion material 30 is disposed on the backside 18 of the mold 10, while the peripheral thermal expansion material 32 is disposed on the front side 16 of the mold 10. The thermal expansion material 34 is central thermal expansion material 34, so-called herein because the central thermal expansion material 34 is disposed within the area (in the X-Y plane) of the pattern 20 of the mold 10. The illustrative central thermal expansion material 34 is embedded in the mold body 14; however, in other embodiments the central thermal expansion material may be disposed on the backside 18 of the mold 10 (or analogously, on the backside 18 of the mold body 14). The thermal expansion material 30, 32, 34 is absorbing for the wavelength or waveband of light that is applied to heat the thermal expansion material 30, 32, 34, and the thermal expansion material 30, 32, 34 has a coefficient of thermal expansion that is large enough that this heating causes the thermal expansion material 30, 32, 34 to expand to a greater extent than the material of the mold body 14, thus imposing a force on the mold body 14 that can be utilized to provide overlay compensation. In some nonlimiting examples, the thermal expansion material 30, 32, 34 comprises a metal. In a more specific nonlimiting example, the thermal expansion material 30, 32, 34 comprises chromium (Cr). However, these are merely nonlimiting examples, and other thermal expansion materials are contemplated, such as a metal, a polymer, or a crystalline material containing C, H, O, N, Si, or various combinations thereof.

Operation of the thermal expansion material 30, 32, 34 for overlay compensation can be summarized as follows. In some embodiments, laser light 36 is applied to the backside 18 of the mold 10, and passes through the mold 10 to illuminate and heat the semiconductor wafer 12. Because the laser light 36 passes through the mold body 14 (e.g., made of fused silica), the same laser light 36 also provides overlay compensation by the mechanism of shaping the mold 10 by inducing thermal expansion of the thermal expansion material 30, 32, 34. The fused silica of the mold body 14 does not absorb (or weakly absorbs) the laser light 36, but laser heating from the laser light 36 can act on the chromium (Cr) shield 30 and/or 32 along the mold edge to deform the mold 10. Additionally or alternatively, the central thermal expansion material 34 can be added in and/or on the backside of the mold body 14, to absorb the laser light 36 and deform the mold. In general, this provides a further degree of freedom for overlay correction-laser heating on the mold. In general, it should be noted that a given NIL mold may include only the peripheral thermal expansion material 30 and/or 32; or may include only the central thermal expansion material 34; or may include both peripheral and central thermal expansion material (as shown in FIG. 1). Furthermore, while laser light 36 is described, the light 36 could be applied by a light emitting diode (LED) or an array of LEDs, an incandescent lamp, or other suitable light source.

The foregoing describes an example in which the same laser light 36 (e.g., a single laser beam) heats both the semiconductor wafer 12 and the thermal expansion material 30, 32, 34. However, it is contemplated to provide a different light source for heating the thermal expansion material 30, 32, 34. As a further variant, a single light source may be used to heat the thermal expansion material 30, 32, 34, but not to heat the wafer 12. For example, this could be the case if the wafer 12 is made of (or predominantly made of) a semiconductor material with a bandgap E_{G}, and the light used has a photon energy that is below that bandgap E_{G} so that the wafer 12 does not absorb (or weakly absorbs) the like. As a specific example, if the wafer 12 is silicon (or predominantly silicon) with a bandgap of about 1.12 eV, and the light is in the infrared below the bandgap of silicon (e.g., wavelength of about 1100 nanometers or lower), then the infrared light will be weakly absorbed by the (here silicon) wafer 12 but strongly absorbed by the (e.g., metal) thermal expansion material 30, 32, 34.

A particular advantage of using a light source that is preferentially or solely absorbed by the thermal expansion material 30, 32, 34 to heat the thermal expansion material 30, 32, 34, but is not absorbed by the wafer 12, is that this light source may be spatially limited in its application to heat a preselected portion of the thermal expansion material disposed in and/or on the mold by applying the light to only the preselected portion of the thermal expansion material. The portion that is heated can be determined based on an overlay error map quantifying a misalignment between the pattern 20 of the NIL mold 10 and a pre-existing pattern disposed on and/or in the semiconductor wafer 12 prior to performing of the NIL, using optimization similar to that employed to optimize the finger actuator forces for example.

In some further contemplated variants, the thermal expansion material 30, 32, 34 may have an anisotropic coefficient of thermal expansion (e.g., expanding more rapidly in the X-Y plane when heated versus in the Z-direction). Although not shown, the thermal expansion material 30, 32, 34 is contemplated to be arranged as a grid or other pattern, for example to facilitate passage of some of the applied light 36 through the thermal expansion material 30, 32, 34 to heat the wafer 12.

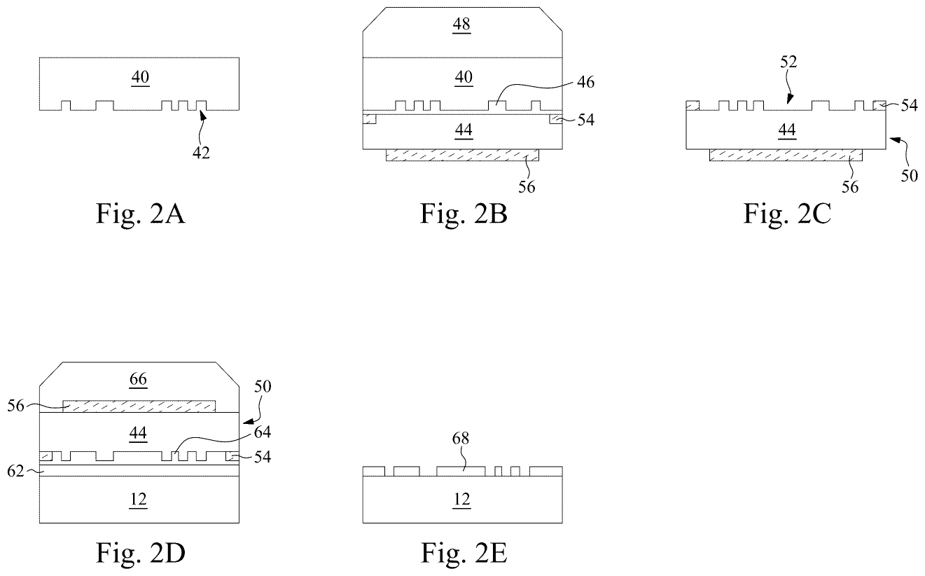

FIGS. 2A, 2B, 2C, 2D, and 2E diagrammatically illustrate an NIL method using a replica NIL mold, by way of successive side cut views. With reference first to FIG. 2A, in this nonlimiting illustrative example the mold is fabricated as a “replica” mold, so-called because the replica mold is created by replicating (in reverse tone) a pattern 42 of a master mold 40 shown in FIG. 2A. The master mold 40 may, for example, comprise quartz, though other materials are contemplated. Formation of the pattern 42 of the master mold 40 is not illustrated, but may for example be done by applying an electron beam (e-beam) sensitive resist to a surface of a master mold blank, writing the pattern to the e-beam sensitive resist using an e-beam, developing the e-beam sensitive resist and etching the pattern through the developed e-beam sensitive resist into the surface of the master mold 40. This process can optionally be repeated two or more times to enable formation of the pattern 42 with (for example) mesas having slanted sidewalls.

FIGS. 2B and 2C diagrammatically illustrate the replication process. As shown in FIG. 2B, a mold body 44 (e.g., made of fused silica in a nonlimiting example) has a resist layer 46 formed on a surface thereof, and the pattern 42 of the master mold 40 is pressed onto the resist 46 to imprint (a reverse of) the pattern 42 of the master mold 40 on the resist 46 coating the mold body 44. In some embodiments, the master mold pressing may be done using an NIL tool. The resist 46 is cured, e.g., using ultraviolet (UV) light 48 illuminated through the master mold 40, and thereafter the master mold 40 is removed. An anisotropic etch with low selectivity between the material of the resist 46 and the material of the mold body 44 is then performed, which transfers the pattern imprinted in the resist 46 to the replica mold to form (as shown in FIG. 2C) a replica mold 50 with pattern 52.

As seen in FIGS. 2B and 2C, the mold body 44 of the replica mold 50 includes thermal expansion material 54 and 56, which in this illustrative example include peripheral thermal expansion material 54 on the frontside of the mold 50, and central thermal expansion material 54 disposed on the backside of the mold 50 in the area (in the X-Y plane) of the pattern 52.

FIGS. 2D and 2E illustrates use of the replica mold 50 for performing NIL on a semiconductor wafer 12 coated with an IC layer 62 to be patterned, and a resist layer 64 disposed on the IC layer 62 to be patterned. The replica mold 50 is pressed onto the resist layer 64 as shown in FIG. 2D to imprint the pattern 52 of the replica mold 50 on the resist layer 64. The imprinted pattern is reversed in that the protrusions of the replica mold 50 are imprinted as recesses in the resist layer 64, and vice versa. In the NIL operation, the thermal expansion material 54, 56 may be utilized to perform overlay compensation (alone, or in combination with other overlay compensation mechanisms such as using finger actuators and/or wafer heating). The resist layer 64 with the imprinted pattern is cured using UV light 66, and thereafter the replica mold 50 is removed. This is followed by an anisotropic etch with low selectivity between the material of the resist layer 64 and the material of the underlying IC layer 62, which transfers the pattern formed by NIL in the resist layer 64 to the IC layer 62. The result is shown in FIG. 2E, including the patterned IC layer 68 formed by the anisotropic etching of the IC layer 62. In a nonlimiting illustrative example, the IC layer 62 may be an interlayer dielectric (ILD) layer, and the openings of the patterned ILD layer 68 in this example may be via openings which are to then be filled with tungsten or another conductive material to form vias of a metallization stack. This is merely an example.

In the example of FIGS. 2A-2E, the master mold 40 is used to produce the replica mold 50 which in turn is used in the NIL. This has certain advantages. Notably, the manufacture of the master mold 40 may be complex (e.g., using multiple e-beam writing/etch steps to form the pattern 42 as a complex three-dimensional pattern), but the manufacture of the replica mold 50 entails a relatively straightforward imprint operation. Advantageously, a single master mold 40 can be used to fabricate a potentially large number of substantially identical replica molds 50, which can be beneficial in scaling up IC fabrication processing by (for example) using multiple NIL tools each employing a corresponding replica mold 50.

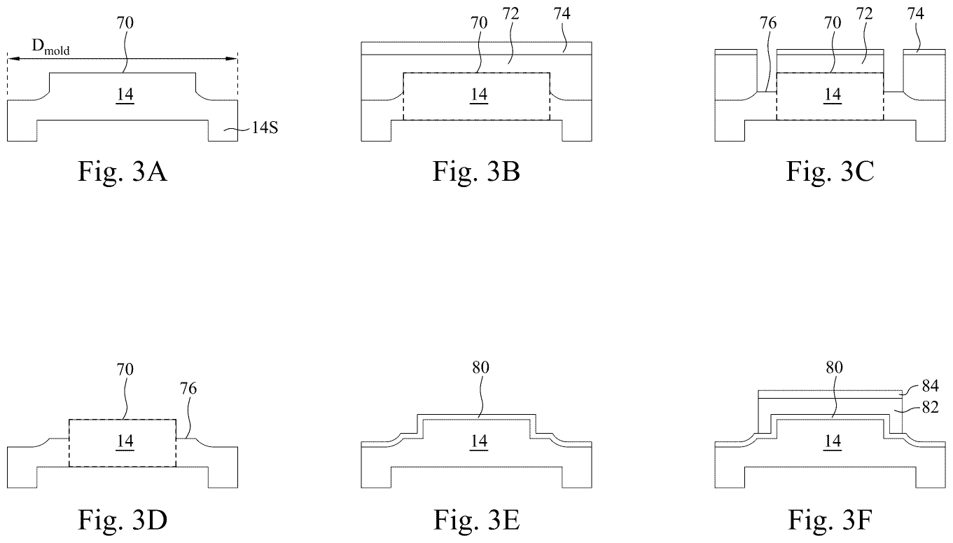

FIGS. 3A, 3B, 3C, 3D, 3E, 3F, 3G, 3H, 3I, 3J, 3K, and 3L diagrammatically illustrate formation of an NIL mold shown in FIG. 3L, by way of successive side cut views shown in FIGS. 3A-3L. This example relates to fabricating an NIL mold that includes only the peripheral thermal expansion material 32. FIG. 3A shows the mold body 14 after initial shaping to form a planar surface 70 on and/or in which the imprint pattern will be formed (hence, the planar surface 70 is on the front side 16 of the mold body 14 as indicated in FIG. 1), and the support feature(s) 14S. In one approach, fabrication of the mold body as shown in FIG. 3A comprises etching of a disk of fused quartz (or other chosen mold body material). The mold body 14 is generally disk-shaped with a diameter D_{mold}. For example, if the NIL mold being fabricated is to be employed in performing NIL on six-inch silicon (or silicon-on-insulator, i.e., SOI) wafers, then the diameter D_{mold} may be about six inches, as a nonlimiting example.

With reference to FIGS. 3B-3D, the mold body 14 is initially processed to recess an outer annulus of the planar surface to form a recessed annular ring 76 around (the remainder of) the planar surface 70 on which the imprint pattern is to be formed. In FIG. 3B, a multilayer resist is formed including resist-B 72 and resist-C 74. The resist layers 72, 74 may, for example, be applied by spin-coating, and may, for example, comprise a resist material containing C, H, O, various combinations thereof, or so forth. FIG. 3C shows patterning of the resist layers 72, 74 by e-beam writing (or photolithography, as another example) followed by dry-etching to transfer the pattern written by the e-beam writing from the resist to the mold body 14. In a nonlimiting example, the dry etching may be performed by plasma etching with a C, O, H, Cl, F or other type of dry etchant. FIG. 3D shows the mold body 14 after removing the resist 72, 74 by wet or dry etching.

With reference to FIGS. 3E-3I, thermal expansion material is formed on the annular ring 76. FIG. 3E shows the mold body 14 with a conformal layer 80 of chromium (or other chosen thermal expansion material) deposited by chemical vapor deposition (CVD), physical vapor deposition (PVD), or another chosen deposition method. FIG. 3F shows the mold body after further deposition of resist layers 82 and 84, which may again be spin-coated and each comprising a resist material containing C, H, O, various combinations thereof, or so forth. FIG. 3G shows the structure after patterning using e-beam writing (or photolithography, as another example) followed by dry-etching to leave the resist 82, 84 only on the annular ring 76. In a nonlimiting example, the dry etching may be performed by plasma etching with a C, O, H, Cl, F or other type of dry etchant. FIG. 3H shows the structure after a further etch step to remove the upper resist layer 84 and a portion of the lower resist layer 82. FIG. 3I shows the structure after chromium etching, e.g., using plasma etching with a C, O, H, Cl, F or other type of dry etchant. This etch is timed to remove the chromium layer 80 except where it is protected by the portion of the lower resist layer 82 remaining on the annular ring 76 (as seen in FIG. 3H). The remaining portion of the chromium layer 80 is thus disposed on the annular ring 76, and constitutes peripheral thermal expansion material 32 as previously described with reference to FIG. 1.

With reference to FIGS. 3J-3L, formation of the imprint pattern 20 on the planar surface 70 is described. As seen in FIG. 3I, the preceding chromium etch removed the chromium layer 80 from the planar surface 70. FIG. 3J shows the structure after deposition of a film 90 by CVD, spin-coating, or another deposition technique, followed by dispensing a resist 92 by spin-coating or the like. The film 90 may for example contain Si, C, H, O, N, various combinations thereof, or so forth. The resist 92 may contain C, H, O, various combinations thereof, or so forth. FIG. 3K shows pattern transfer from the master mold 40 to the resist 92 by imprinting, as previously described with reference to FIG. 2B. FIG. 3L shows the final (replica) mold 10 after dry etching (e.g., using a plasma etch with a C, O, H, Cl, F or other type of dry etchant) to transfer the pattern imprinted in the resist 92 to the planar surface 70 to form the imprint pattern 20.

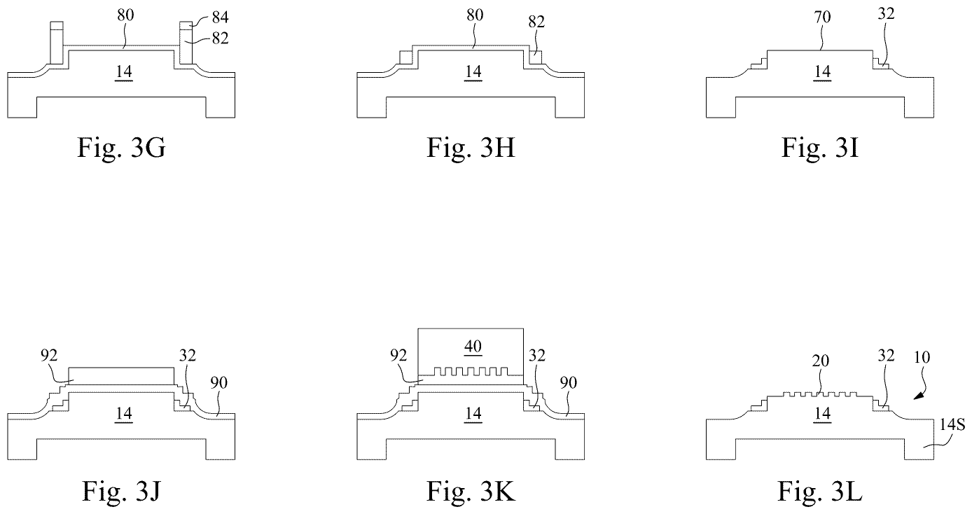

FIGS. 4A, 4B, 4C, 4D, 4E, 4F, 4G, 4H, 4I, 4J, and 4K diagrammatically illustrate formation of an NIL mold blank (that is, an NIL mold before the imprint pattern is formed) shown in FIG. 4K, by way of successive side cut views shown in FIGS. 4A-4K. This example relates to fabricating an NIL mold that includes only the embedded central thermal expansion material 34. FIG. 4A shows the starting mold body 14, and is the same as that of FIG. 3A in the previous example. FIG. 4B shows deposition of a film 100 and resist 102 on the backside of the mold body 14. The film 100 may, for example, be conformally deposited by CVD, and may contain Si, C, H, O, various combinations thereof, or so forth. The resist 102 may be formed by spin-coating, and may contain C, H, O, various combinations thereof, or so forth. FIG. 4C shows the structure after e-beam writing to pattern the resist 102 to form openings therein. (Alternatively, photolithography could be used). FIG. 4D shows the structure after dry etching to transfer the pattern of openings in the resist 102 into the mold body 14 to form openings 104 in the mold body 14. The dry etching may be performed by plasma etching with a C, O, H, Cl, F or other type of dry etchant.

FIGS. 4E and 4F illustrate a variant fabrication approach that can be employed in place of FIGS. 4B and 4C, respectively. In the variant approach of FIGS. 4E and 4F, the film 100 is deposited by spin coating, and is not conformal and is thicker than the example of FIG. 4B. FIG. 4F shows the structure after the e-beam writing of the resist 102, analogous to FIG. 4C. The dry etching in this variant approach may need to be of longer duration to etch through the thicker film 100 (compare FIGS. 4F and 4C).

With reference to FIG. 4G, the structure of FIG. 4F is next processed by depositing a thermal expansion material layer 106 onto the backside of the mold body 14. As seen in FIG. 4G, the thermal expansion material layer 106 is not necessarily conformally deposited, and is thick enough to fill the openings 104 in the backside of the mold body 14. The thermal expansion material may be, by way of nonlimiting examples, a metal, a polymer, or a crystalline material containing C, H, O, N, Si, or various combinations thereof, with the thermal expansion material chosen to have a desired (isotropic or anisotropic) coefficient of thermal expansion. FIG. 4H shows deposition of a resist 110, 112 on the backside of the mold body 14. Each resist 110, 112 may be formed by spin-coating, and may contain C, H, O, various combinations thereof, or so forth. FIG. 4I shows the structure after e-beam writing to pattern the resist 112 and dry etching to remove the resist 112 and the resist 110 except for portions disposed over (and hence providing protection for) the areas corresponding to openings 104 (see FIG. 4D). The dry etching may be performed by plasma etching with a C, O, H, Cl, F or other type of dry etchant. FIG. 4J shows the structure after a further etching process to remove (most of) the thermal expansion material layer 106. The etching is timed in combination with the etch resistance of the remaining regions of the resist 110 to leave portions of the thermal expansion material in the openings 104. These remaining portion of thermal expansion material in the openings 104 constitute the (central) thermal expansion material 34 of the NIL mold under fabrication (cf. FIG. 1). The dry etching may be performed by plasma etching with a C, O, H, Cl, F or other type of dry etchant. FIG. 4K shows the final mold blank after blocking in the (central) thermal expansion material 34 by silicon dioxide (SiO₂) material 114 that fills the remaining portions of the openings 104, so that the thermal expansion material 34 is now embedded in the mold body 14. (Note, the SiO₂ material 114 is similar to the fused silica of the example mold body 14; if the mold body is made of a different material then a suitably compatible filler material can be used in place of the SiO₂ portions 114). The SiO₂ portions 114 can, for example, be deposited by CVD, PVD, or another suitable technique in conjunction with photolithographic delineation of the deposition areas. FIG. 4K thus illustrates a mold blank that can be further processed by transferring an imprint pattern to the frontside planar surface 70.

Employing the blocking material 114 to embed the thermal expansion material 34 inside the mold body 14 can be beneficial, for example by sealing the thermal expansion material 34 against exposure to cleaning solution used in cleaning the NIL mold between uses.

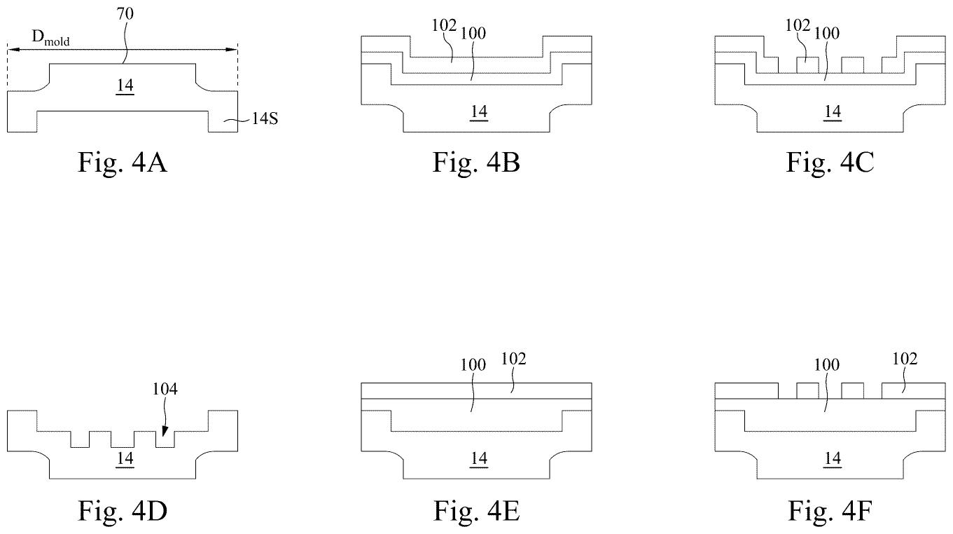

With reference to FIG. 5, however, in a variant embodiment (central) thermal expansion material 34′ is fabricated in accordance with the operations described with reference to FIGS. 4A-4J, but with the etching to remove the thermal expansion material layer 106 being reduced in duration to leave the thermal expansion material 34′ substantially filling the entireties of the openings 104, as seen in FIG. 5. In this variant, the final SiO₂ blocking of FIG. 4K is omitted, and FIG. 5 depicts a mold blank that could be further processed to add the imprint pattern to the frontside planar surface 70. Although not shown, it is contemplated to deposit a thin conformal silicon dioxide layer on the backside of the structure shown in FIG. 5 to provide a thin layer of protection for the thermal expansion material 70.

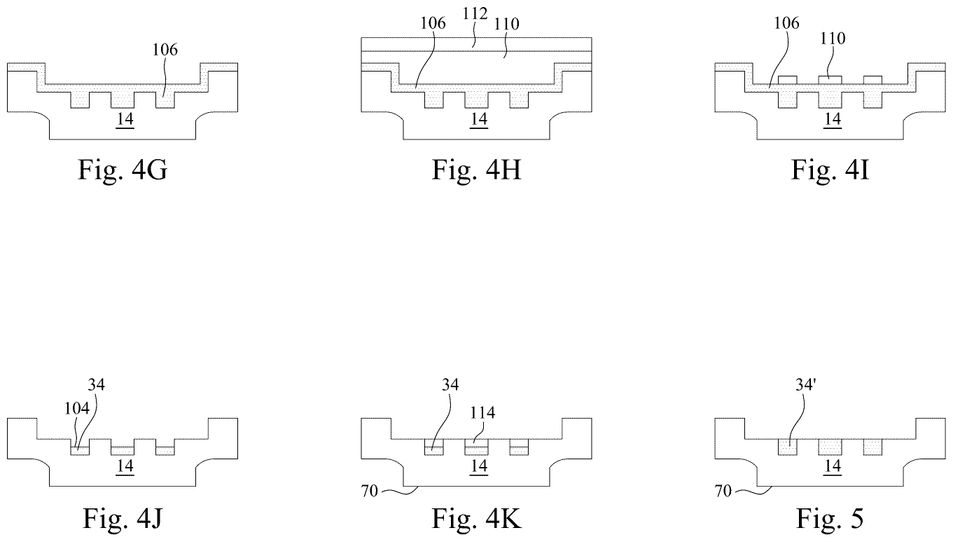

FIGS. 6A, 6B, 6C, and 6D diagrammatically illustrates formation of an NIL mold shown in FIG. 6D from the NIL mold blank shown in FIG. 4K, by way of successive side cut views shown in FIGS. 6A-6D. FIG. 6A shows the same mold blank as FIG. 4K, except FIG. 6A shows the mold blank flipped over so that the front side planer surface 70 is facing up. The imprint transfer process is analogous to that previously described with reference to FIGS. 3J-3L. FIG. 6B shows the structure after deposition of the film 90 by CVD, spin-coating, or another deposition technique, followed by dispensing the resist 92 by spin-coating or the like, as previously described with reference to FIG. 3J. FIG. 6C shows pattern transfer from the master mold 40 to the resist 92 by imprinting, as previously described with reference to FIG. 3K. FIG. 6D shows the final (replica) mold 10 after dry etching (e.g., using a plasma etch with a C, O, H, Cl, F or other type of dry etchant) to transfer the pattern imprinted in the resist 92 to the planar surface 70 to form the imprint pattern 20. The example NIL mold 10 of FIG. 6D includes the central thermal expansion material 34 sealed by blocking SiO₂ material 114 of the starting mold blank of FIG. 6A (which is identical with the mold blank of FIG. 4K).

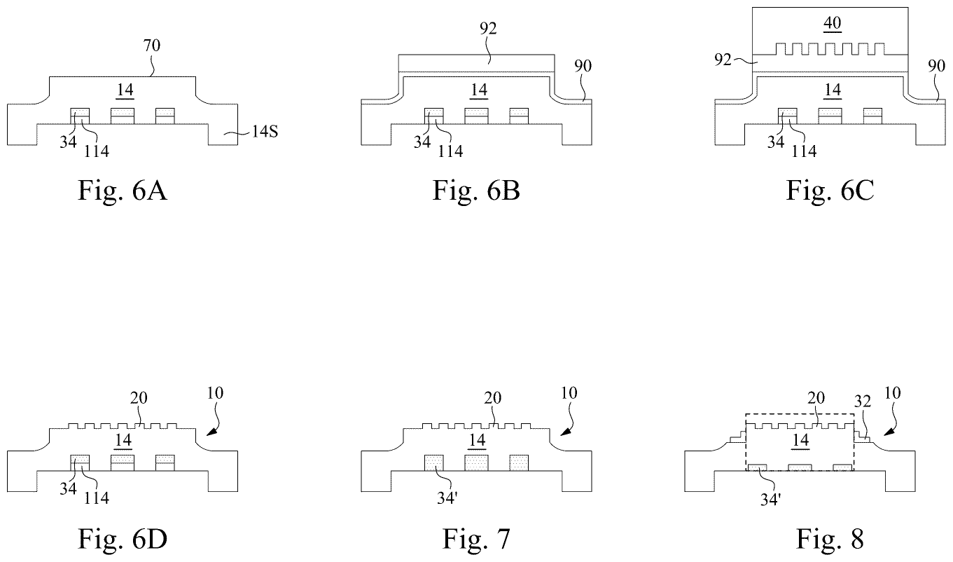

FIG. 7 diagrammatically illustrates a cut view of a variant NIL mold 10 which is manufactured from the mold blank of FIG. 5, rather than the mold blank of FIG. 4K. The process for FIG. 7 is the same as the process just described with reference to FIGS. 6A-6D, except that the mold blank shown in FIG. 6A is replaced by the mold blank of FIG. 5. Consequently, the NIL mold of FIG. 7 includes the unsealed central thermal expansion material 34′ of the starting mold blank of FIG. 6A.

FIG. 8 diagrammatically illustrates a cut view of an NIL mold 10 that includes both the peripheral thermal expansion material 32 formed in accordance with relevant operations of FIGS. 3E-3I, and the unsealed central thermal expansion material 34′ formed in accordance with relevant operations of FIGS. 4A-4J.

More generally, it is to be appreciated that the mold fabrication workflows described herein with reference to FIGS. 2A-2E, 3A-3L, 4A-4K, and 6A-6D are nonlimiting illustrative examples, and that other workflows including suitable combinations of processing operations (e.g., by e-beam writing and/or photolithography and etching, spin-coating, CVD, et cetera) can be used to fabricate an NIL mold with thermal expansion material disposed in and/or on the mold, so that overlay correction can be performed during the NIL by heating the thermal expansion material disposed in and/or on the mold by applying light to the thermal expansion material.

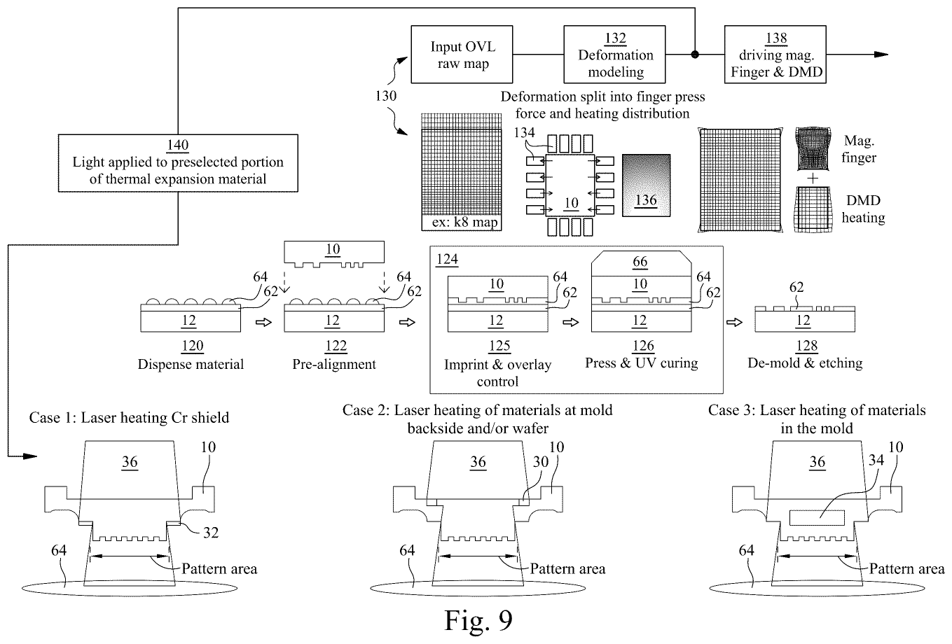

FIG. 9 diagrammatically illustrates, by way of plan and side cut views, an NIL process including optical overlay compensation applied to the mold 10, according to three nonlimiting illustrative embodiments designated: Case 1, Case 2, and Case 3. The process sequence starts with a “Dispense material” step 120 in which resist 64 is dispensed (e.g., by spin coating) onto an IC layer 62 of a semiconductor wafer 12 that is to be patterned. In a pre-alignment step 122, the NIL mold 10 (which here is a replica mold, though the NIL mold 10 does not need to be a replica mold) is aligned with the wafer 12. In an NIL operation 124, the mold 10 is pressed onto the resist 64 and the imprinted resist 64 is UV cured using UV light 66. In one implementation of the NIL operation 124, imprint and overlay control 125 is used to perform overlay compensation during the pressing and/or UV curing 126. After the NIL operation 124, in an operation 128 the mold 10 is removed (i.e., demolding) and subsequent processing is performed, such as etching to transfer the imprinted pattern from the resist 64 to the IC layer 62 of the semiconductor wafer 12.

The overlay compensation 125 utilizes a measured overlay error map 130 acquired using one or more metrology tools such as a scanning electron microscope (SEM), an optical diffraction measurement tool, a combination thereof, or so forth, as nonlimiting illustrative examples. The measured overlay error map 130 may, for example, comprise or represent a two-dimensional vector field indicating the error (as a function of x, y position) of the pattern to be imprinted by the NIL step respective to designated alignment marks or features in the wafer 12 or layers thereof (e.g., IC layer 62 or another layer of the IC-under-fabrication) as determined by the metrology tool(s). In FIG. 9, the overlay error map 130 is also labeled as the input overlay (OVL) raw map, and it will be appreciated that other types of nomenclature may be used for this input information.

The overlay error map 130 is input to deformation modeling 132 which determines overlay compensation parameters, which in the illustrative example include finger actuator settings for setting the forces applied by respective finger actuators 134 that engage the edges of the NIL mold 10. The finger actuators 134 may be piezoelectric actuators, for example, and by a suitable combinations of forces applied by the respective finger actuators 134 overlay compensation can be implemented by way of adjusting the position and/or geometry of the mold 10. Such adjustment can be translational, rotational, and/or magnification adjustments, for example. Additionally or alternatively, the deformation modeling 132 can determine settings of a digital mirror device (DMD) that directs illumination through the mold 10 onto the underlying semiconductor wafer 12 to produce a heating distribution 136 on the wafer 12, thereby implementing overlay compensation by inducing localized thermal expansion of the wafer 12. The resulting overlay compensation in the form of a set of finger actuator signals and DMD settings 138 implements the desired overlay compensation.

However, these overlay compensation techniques employing the finger actuators 134 and a wafer heating distribution 136 may be insufficient and/or undesirable in certain cases. For example, the ability to use heating of the semiconductor wafer 12 to achieve overlay compensation could be limited by thermal sensitivity of features of the pre-existing pattern disposed on and/or in the semiconductor wafer. The finger actuators may be limited in their ability to provide precise localized overlay compensation, since they operate on the mold as a whole.

Hence, in the embodiment of FIG. 9, an additional overlay compensation mechanism is advantageously provided by the thermal expansion material 30, 32, and/or 34 being illuminated by laser light 36, as diagrammatically shown in the lower portion of FIG. 9. To do so, the deformation modeling 132 also determines a preselected portion 140 of the thermal expansion material 30, 32, and/or 34 that is to be heated by application of the laser light 36. The preselected portion could, in some embodiments, include all of the available thermal expansion material. In some embodiments, the deformation modeling 132 may also determine an (average) optical power applied by the laser light 36. The optical power can be controlled by controlling the intensity of the laser light 36, or the average optical power could be controlled by controlling pulse widths and/or pulse repetition rate of the (in this approach pulsed) laser light 36. As previously noted, the laser light 36 could be the same laser light used to produce the heating distribution 136 on the wafer 12 (in which case the deformation modeling 132 would need to co-optimize the heating distribution 136 and the preselected portion 140 of the thermal expansion material 30, 32, and/or 34 that is to be heated), or could be a different light source.

The bottom portion of FIG. 9 diagrammatically shows, by way of side cut views, three nonlimiting illustrative Cases for the overlay compensation by the thermal expansion material: Case 1 which employs the front side peripheral thermal expansion material 32; Case 2 which employs the backside peripheral thermal expansion material 30; and Case 3 which employs the central thermal expansion material 34. While these three Cases are considered independently here, it will be appreciated that two or more of these Cases could be combined; e.g., Case 1 and Case 3 could be combined in the example mold of FIG. 8 which includes both front side peripheral thermal expansion material 32 and (in FIG. 8 backside) central thermal expansion material 34'.

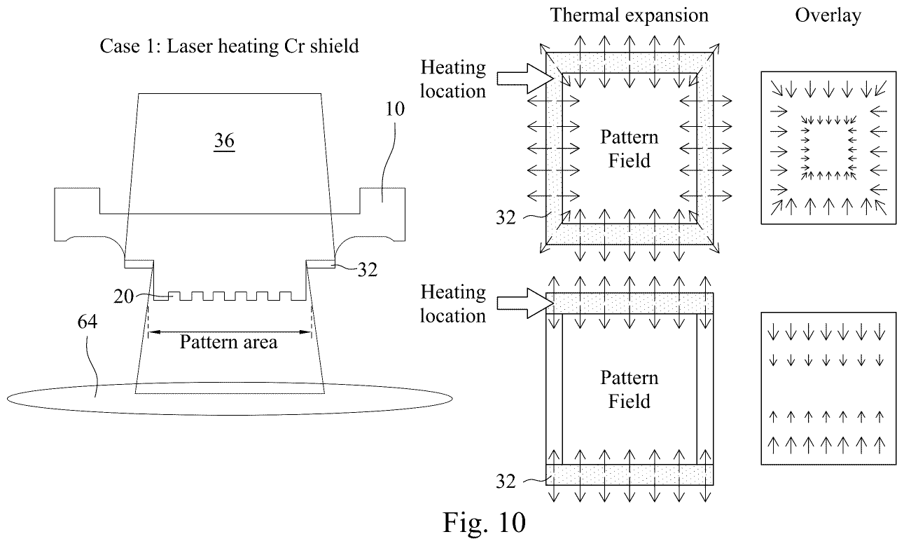

FIG. 10 diagrammatically illustrates Case 1 of FIG. 9. Here, the front side peripheral thermal expansion material 32 expands, which has the effect of compressing the pattern 20 of the mold 10 (see plan view drawings titled “Thermal expansion”), which provides overlay compensation as shown in the plan view drawings titled “Overlay”. FIG. 10 shows two examples (in both examples, the imprint pattern 20 is rectangular). In one example, the front side peripheral thermal expansion material 32 encircles the pattern 20, and the overlay correction thus compresses the pattern 20 two-dimensionally by the thermal expansion of the peripheral thermal expansion material 32 produced by the applied light 36. In the other example, the front side peripheral thermal expansion material 32 is disposed only on two opposite sides of the pattern, and the overlay correction compresses the pattern 20 one-dimensionally by thermal expansion of the thermal expansion material produced by the applied light 36.

In a variant implementation of the latter one-dimensional compression of the pattern 20, the peripheral thermal expansion material 32 could still encircle the pattern 20, but the overlay correction applies the light to only a preselected portion of the encircling peripheral thermal expansion material (namely, the portions corresponding to the top and bottom edges in the example of FIG. 10).

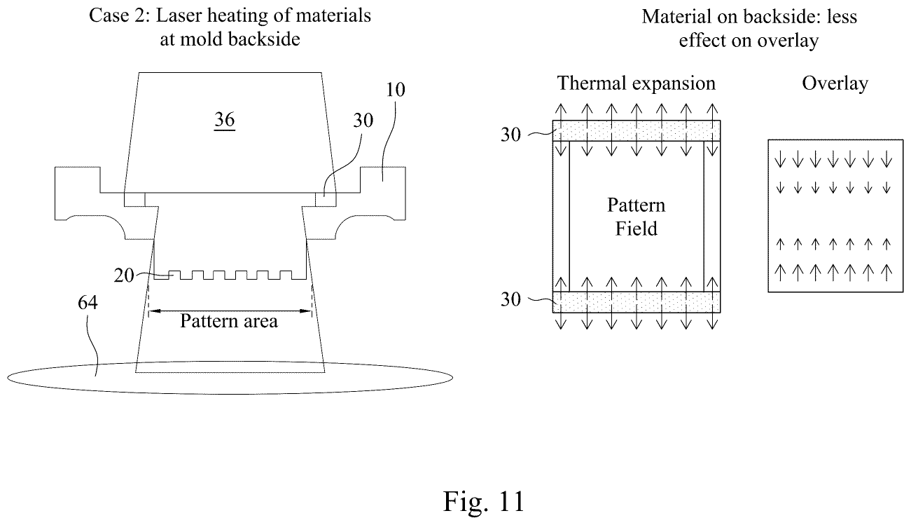

FIG. 11 diagrammatically illustrates Case 2 of FIG. 9. Here, the backside peripheral thermal expansion material 30 expands, which has the effect of compressing the pattern 20 of the mold 10 (see plan view drawing titled “Thermal expansion”), which provides overlay compensation as shown in the plan view drawing titled “Overlay”. FIG. 11 shows only the example in which the pattern 20 is rectangular and the backside thermal expansion material 30 is disposed only on two opposite sides of the pattern 20. As was the case in FIG. 10, the overlay correction compresses the pattern 20 one-dimensionally by thermal expansion of the thermal expansion material produced by the applied light 36. However, because the backside thermal expansion material 30 is more distant from the pattern 20 than the front side thermal expansion material 32 of the example of FIG. 10, the thermal expansion of the backside thermal expansion material 30 has less effect on the overlay than the thermal expansion of the front side thermal expansion material 32.

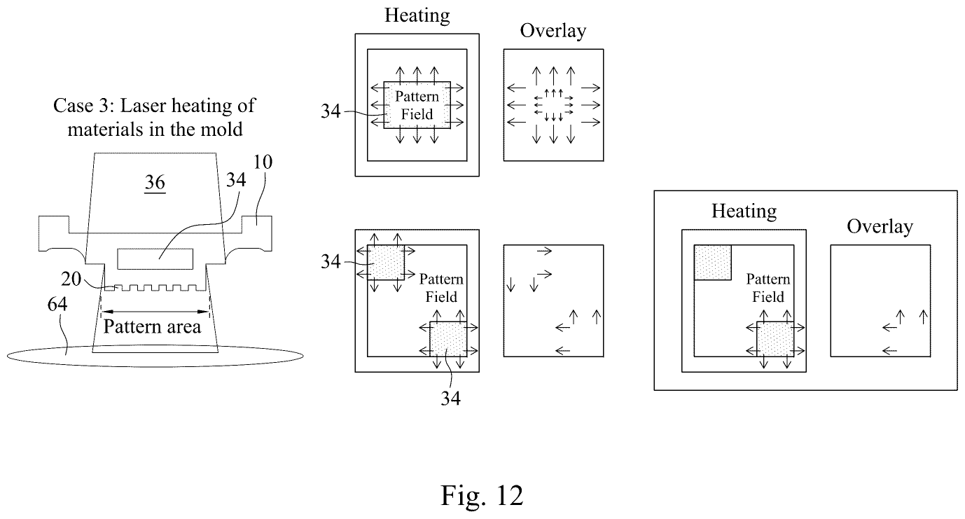

FIG. 12 diagrammatically illustrates Case 3 of FIG. 9. Here, the central thermal expansion material 34 expands, which has the effect of expanding the pattern 20 of the mold 10 (see plan view drawings titled “Heating”), which provides overlay compensation as shown in the plan view drawings titled “Overlay”. FIG. 10 shows two examples, corresponding to different portions of the central thermal expansion material 34 being illuminated by the applied light 36 and thus heated. In one example, a single center portion of the central thermal expansion material 34 is illuminated and heated; while, in the other example, two opposite corner portions of the central thermal expansion material 34 are illuminated and heated. The different overlay compensation provided by these two cases is also shown. It will be appreciated that other preselected portion(s) of the central thermal expansion material 34 could be illuminated and heated to produce other patterns of localized overlay compensation.

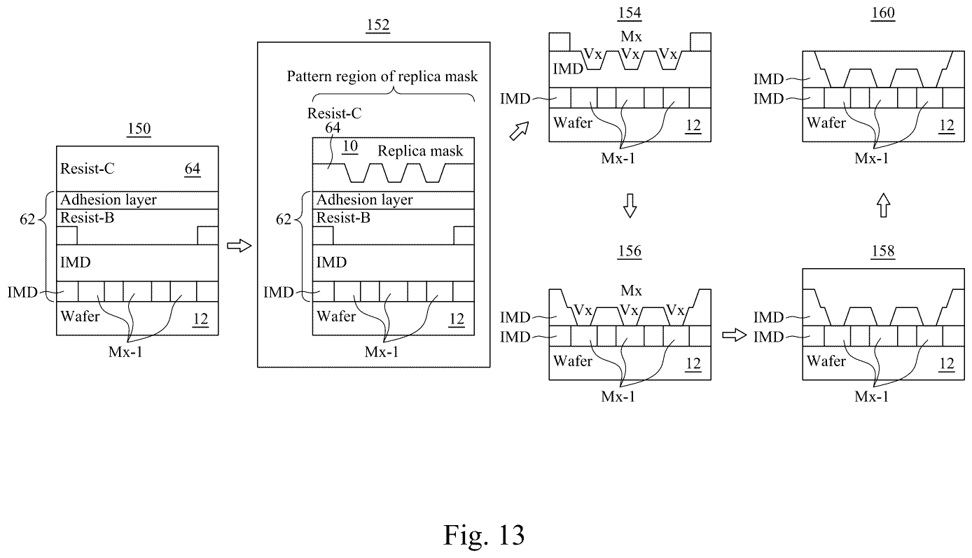

FIG. 13 diagrammatically illustrates a via formation process using NIL with overlay compensation as disclosed herein. Here, the starting structure 150 includes a wafer 12 with an IC layer 62 that includes a portion of a metallization stack including underlying metallization Mx-1 and an intermetal dielectric layer IMD into which via openings are to be formed, along with resist layers and an adhesion layer. The resist layer 64 is disposed on the adhesion layer. The various layers may, for example, contain C, H, O, various combinations thereof, or so forth.

The NIL process 152 is performed as described herein using the mold 10 to imprint via openings with slanted sidewalls. (That is, the imprint pattern 20 on the mold 10 in this example includes mesas with slanted sidewalls). The NIL process 152 may employ heating of the thermal expansion material 30, 32, and/or 34 of the mold 10 as previously described.

In an operation 154, dry etching is performed to transfer the via pattern from the resist 64 to the IMD, including via openings Vx and a metallization pattern Mx. The dry etching is an anisotropic etch with low etching selectivity to transfer the pattern from the resist 64 to the IMD layer. The anisotropic etching enables transfer of an asymmetric via Vx profile since the wedge-shaped Vx opening in the resist 64 is transferred downward by the anisotropic etching. The etching used in operation 154 may, for example, be plasma etching with C, O, H, Cl, F, or another dry etchant.

In a further dry etching step 156, the via openings Vx and metal pattern Mx are transferred further downward until the via openings Vx expose the underlying metallization Mx-1. Operation 156 can again use plasma etching with C, O, H, Cl, F, or another dry etchant.

In an operation 158, metal material is applied to fill the via openings Vx and the metallization pattern Mx. In one suitable approach, the metal material is copper and electroplating is used for the operation 154. In an operation 160, chemical mechanical polishing (CMP) is performed to remove excess metal from the surface.

The via formation process of FIG. 13 is a nonlimiting illustrative example of one application of NIL using the thermal expansion material as disclosed herein, and the disclosed overlay compensation using the thermal expansion material is not limited to this one illustrative example. In some embodiments, the controller of the NIL tool may be modified to include a control knob (or virtual control knob, e.g., softkeys or the like) for selecting the overlay compensation using the thermal expansion material. When the overlay compensation using the thermal expansion material is selected, the deformation modeling 132 (see FIG. 9) is modified to include the additional degree of freedom of selecting the portion of the thermal expansion material to which light is to be applied.

In the following, some further embodiments are described.

In a nonlimiting illustrative embodiment, a lithography method includes: performing nanoimprint lithography (NIL) to imprint a pattern of a mold onto a layer disposed on a semiconductor wafer by pressing the pattern of the mold onto the layer; and performing overlay correction during the NIL by heating a thermal expansion material disposed in and/or on the mold by applying light to the thermal expansion material.

In a nonlimiting illustrative embodiment, a method includes: forming a pre-layer on a substrate; forming a resist layer over the pre-layer; imprinting a mold into the resist layer; generating an adjusted mold by adjusting a position of a pattern of the mold by heating thermal expansion portions on the mold; patterning the resist layer using the adjusted mold; removing the mold from the resist layer; and transferring a pattern of the resist layer to the pre-layer.

In a nonlimiting illustrative embodiment, a nanoimprint lithography (NIL) mold for imprinting a pattern on a semiconductor wafer is disclosed. The NIL mold includes: a mold body; an imprint pattern formed on a front side of the mold body; and thermal expansion material disposed in and/or on the mold body.

An NIL mold includes a mold body, an imprint pattern formed on a front side thereof, and thermal expansion material disposed in and/or on the mold body.

A NIL method includes imprinting a pattern of a mold onto a layer disposed on a semiconductor wafer by pressing the pattern onto the layer, and performing overlay correction during the NIL by heating a thermal expansion material disposed in and/or on the mold by applying light thereto.

A method includes: forming a pre-layer on a substrate; forming a resist layer over the pre-layer; imprinting a mold into the resist layer; generating an adjusted mold by adjusting a position of a pattern of the mold by heating thermal expansion portions on the mold; patterning the resist layer using the adjusted mold; removing the mold from the resist layer; and transferring a pattern of the resist layer to the pre-layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography method comprising:
performing nanoimprint lithography (NIL) to imprint a pattern of a mold onto a layer disposed on a semiconductor wafer by pressing the pattern of the mold onto the layer; and
performing overlay correction during the NIL by heating a thermal expansion material disposed in and/or on the mold by applying light to the thermal expansion material.

2. The lithography method of claim 1, wherein:
the thermal expansion material includes peripheral thermal expansion material disposed outside the pattern of the mold; and
the overlay correction includes compressing the pattern by thermal expansion of the peripheral thermal expansion material produced by the applied light.

3. The lithography method of claim 2, wherein the pattern is rectangular, the peripheral thermal expansion material encircles the pattern, and the overlay correction includes applying the light to a preselected portion of the peripheral thermal expansion material encircling the pattern.

4. The lithography method of claim 2, wherein the pattern of the mold is disposed on a front side of the mold and the peripheral thermal expansion material is disposed on the front side of the mold and/or on a backside of the mold opposite the front side of the mold.

5. The lithography method of claim 1, wherein the thermal expansion material includes central thermal expansion material disposed within an area of the pattern of the mold; and
the overlay correction includes expanding the pattern by thermal expansion of the central thermal expansion material produced by the applied light.

6. The lithography method of claim 5, wherein the central thermal expansion material includes two or more mutually disconnected portions of the central thermal expansion material disposed at corresponding two or more regions of the pattern.

7. The lithography method of claim 5, wherein the pattern of the mold is disposed on a front side of the mold and the central thermal expansion material is disposed on a backside of the mold opposite the front side of the mold and/or is embedded within the mold.

8. The lithography method of claim 1, wherein the overlay correction includes heating a preselected portion of the thermal expansion material disposed in and/or on the mold by applying light to only the preselected portion of the thermal expansion material.

9. The lithography method of claim 8, further comprising:
determining the preselected portion of the thermal expansion material based on an overlay error map quantifying a misalignment between the pattern of the mold and a pre-existing pattern disposed on and/or in the semiconductor wafer prior to performing of the NIL.

10. The lithography method of claim 1, wherein the applying of the light to the thermal expansion material includes applying the light in the ultraviolet, visible, and/or infrared range to the thermal expansion material.

11. The lithography method of claim 1, wherein the layer disposed on the semiconductor wafer is a resist layer, and the performing the NIL includes performing ultraviolet curing of the resist layer while the pattern of the mold onto the layer is pressing onto the resist layer.

12. The lithography method of claim 1, wherein the overlay correction further includes at least one of (i) applying force to a periphery of the mold using finger actuators, and/or (ii) applying wafer-heating light to the semiconductor wafer in at least a portion of the area of the pattern.

13. A method comprising:
forming a pre-layer on a substrate;
forming a resist layer over the pre-layer;
imprinting a mold into the resist layer;
generating an adjusted mold by adjusting a position of a pattern of the mold by heating thermal expansion portions on the mold;
patterning the resist layer using the adjusted mold;
removing the mold from the resist layer; and
transferring a pattern of the resist layer to the pre-layer.

14. The method of claim 13, wherein the heating of the thermal expansion portions on the mold comprises applying light to the mold.

15. The method of claim 13, further comprising curing the resist layer during the patterning using ultraviolet (UV) light, wherein the adjusting is performed before or during the curing.

16. The method of claim 13, wherein the transferred pattern comprises via openings formed in the pre-layer.

17. A nanoimprint lithography (NIL) mold for imprinting a pattern on a semiconductor wafer, the NIL mold comprising:
a mold body;
an imprint pattern formed on a front side of the mold body; and
thermal expansion material disposed in and/or on the mold body.

18. The NIL mold of claim 17, wherein the thermal expansion material includes peripheral thermal expansion material disposed outside the imprint pattern on the front side of the mold body and/or on a backside of the mold body opposite the front side of the mold body.

19. The NIL mold of claim 17, wherein the thermal expansion material includes central thermal expansion material disposed within an area of the imprint pattern, the central thermal expansion material being disposed on a backside of the mold body opposite the front side of the mold body and/or embedded within the mold body.

20. The NIL mold of claim 17, wherein the mold body comprises a non-crystalline ceramic material and the thermal expansion material comprises a metal.
